(19) United States
(12) Patent Application Publication
(10) Pub. No.: US 2022/0314421 A1
(43) Pub. Date: Oct. 6, 2022

(54) METHOD AND WORK APPARATUS WITH SOUND ADAPTATION

(71) Applicant: Andreas Stihl AG & Co. KG, Waiblingen (DE)

(72) Inventors: Sebastian Junker, Ludwigsburg (DE); Sid Tossenberger, Munich (DE)

(21) Appl. No.: 17/708,902

(22) Filed: Mar. 30, 2022

(30) Foreign Application Priority Data
Mar. 30, 2021 (EP) 21166109.5

(51) Int. Cl. B25F 5/00; B23B 45/02

(52) U.S. Cl. CPC B25F 5/001; B23B 45/02; B25D 2250/221; B25D 2250/091

(57) ABSTRACT

The disclosure relates to a method for sound adaptation, via a sound generator, of a handheld work apparatus driven by an electric drive motor and to a handheld work apparatus with a sound generator configured for this purpose. The work apparatus generates during operation an uncorrected operating sound. Via the sound generator, during operation a supplementary sound is generated in addition to the uncorrected operating sound and is overlaid on the operating sound to form an overall sound with an overall sound pressure level (LGₚ). In this case, the main component of the supplementary sound lies in an adaptation frequency spectrum (f_{A}) below 1 kHz.

### CROSS REFERENCE TO RELATED APPLICATION

This application claims priority of European patent application no. 21166109.5, filed Mar. 30, 2021, the entire content of which is incorporated herein by reference.

### TECHNICAL FIELD

The disclosure relates to a method for sound adaptation, via a sound generator, of a handheld work apparatus driven by an electric drive motor, to a handheld work apparatus configured for this purpose and to a suitable conversion assembly.

### BACKGROUND

Depending on the intended use, handheld work apparatuses are fitted either with an internal combustion engine or with an electric motor. In the case of high-power work apparatuses, internal combustion engines dominate. The distinctive operating sound of such a work apparatus driven by an internal combustion engine is a sign of power and high performance. An experienced user can discern and evaluate the current operating state and also the applied operating load from the operating sound.

Electrically driven work apparatuses are quieter in comparison. This fact and the absence of exhaust gases mean that they can be used particularly well in densely populated areas. Battery-powered apparatuses are also not restricted in their operation by a power cable, or indeed by the availability of a mains voltage connection. Electrically driven apparatuses have also by now achieved impressive levels of performance.

Nevertheless, the comparatively low sound level does not only have advantages. The user gets less acoustic feedback from the work performed, and so evaluation of the working situation is more difficult. The performance capabilities are underestimated. This is detrimental to acceptance as a fully fledged work apparatus, which stands in the way of the otherwise desirable substitution of the internal combustion engine by an electric drive.

### SUMMARY

It is an object of the disclosure to provide a method for sound adaptation of a handheld work apparatus driven by an electric drive motor that improves the acoustic feedback to the user.

This object can, for example, be achieved by a method for sound adaptation of a handheld work apparatus via a sound generator, wherein the handheld work apparatus includes an electric motor configured to drive the work apparatus, wherein the work apparatus generates during operation an uncorrected operating sound with an operating sound pressure level. The method includes: generating a supplementary sound via the sound generator in addition to the uncorrected operating sound during operation; and, overlaying the supplementary sound on the uncorrected operating sound to form an overall sound with an overall sound pressure level, wherein a main component of the supplementary sound lies in an adaptation frequency range below 1 kHz.

It is a further object of the disclosure to provide a work apparatus adapted for this purpose.

This object can, for example, be achieved by a handheld work apparatus including: an electric drive motor; a sound generator; wherein the work apparatus generates, during operation, an uncorrected operating sound with an operating sound pressure level; the sound generator being configured to generate a supplementary sound via the sound generator in addition to the uncorrected operating sound during operation; and, overlay the supplementary sound on the uncorrected operating sound to form an overall sound pressure level, wherein a main component of the supplementary sound lies in an adaptation frequency range below 1 kHz.

It is a further object to provide an assembly for sound adaptation with which an existing work apparatus can be easily retrofitted.

This object can, for example, be achieved by an assembly for sound adaptation of a handheld work apparatus driven by an electric drive motor. The assembly includes: a hand protection of the work apparatus; a sound generator having a speaker; wherein the work apparatus generates, during operation, an uncorrected operating sound with an operating sound pressure level; the sound generator being configured to generate a supplementary sound via the sound generator in addition to the uncorrected operating sound during operation; and, overlay the supplementary sound on the uncorrected operating sound to form an overall sound pressure level, wherein a main component of the supplementary sound lies in an adaptation frequency range below 1 kHz.

A basis of the disclosure is firstly the finding that it is not the absolute volume that provides advantageous acoustic feedback, but what matters instead is a specific distribution of the sound level within the audible frequency spectrum. The disclosure is also based on the finding that the subjective perception of power and high performance, but also the objective perception of changes in load during operation are primarily determined by the lower frequencies in the range below 1 kHz. While work apparatuses with an internal combustion engine produce significant sound components in this low frequency range, such sound components of the operating sound in the case of electrically operated work apparatuses in the uncorrected state according to the prior art are much less pronounced and are therefore not available to the user as acoustic feedback.

On the basis of these findings, it is therefore provided according to the disclosure that during operation a supplementary sound is generated in addition to the uncorrected operating sound via a sound generator configured for this purpose and is overlaid on the operating sound to form an overall sound with an overall sound pressure level, and the main component of the supplementary sound lies in an adaptation frequency range below 1 kHz. As a result, two results are primarily achieved: on the one hand, the subjective and objective perception of the resultant overall sound in the sense of acoustic feedback for the user is significantly improved. Confidence in the performance capability of the apparatus increases, and the actual operating state can be better perceived, for example on the basis of variations in speed. On the other hand, the priority given by the disclosure to the range below 1 kHz does not lead to any appreciable, or even slight, increase in the weighted cumulative overall sound pressure level, and so the overall volume perceived by human hearing remains substantially unchanged. The benefits of the electric drive, in particular with regard to acceptance in densely populated areas, remain. This applies in particular to the case where the supplementary sound is set at such a level that the A-weighted cumulative overall sound pressure level is not more than 1.0 dB(A) and in particular not more than 0.5 dB(A) greater than the A-weighted cumulative operating sound pressure level of the uncorrected operating sound.

The supplementary sound has sound energy distributed over its frequency range. As an essential prerequisite for achieving the benefits described above, it has already been mentioned that the main component of the supplementary sound lies in an adaptation frequency range below 1 kHz. For this, advantageously at least 70%, preferably least 80% and in particular at least 90% of the sound energy of the supplementary sound is generated in the adaptation frequency range. This ensures that on the one hand the sound perception is corrected in the desired way, while on the other hand the cumulative overall sound pressure level characterizing the volume perception does not increase, or does not considerably increase.

In an embodiment, the speed of a drive shaft, in particular of the drive motor, is used as a fundamental frequency for establishing the supplementary sound, the supplementary sound being set as dependent on the fundamental frequency. Changes in the speed consequently also lead in an analogous way to changes in the supplementary sound. As a result, the speed actually achieved can be perceived better. In particular, however, variations in speed can be acoustically identified much better, and so the user develops a better feel for what load the tool experiences, for example in the form of a saw chain when it is sawing into the wood. The user can consequently set the pressure to be exerted on the saw blade, or in the case of a hedge trimmer the advancement through the branch, more easily and with better sensitivity.

The effects described above are particularly pronounced in an embodiment, in which the adaptation frequency range of the supplementary sound includes at least one single frequency band and in particular a number of frequency bands, the frequency band including a reference frequency with a maximum sound pressure level, and the reference frequency being set as dependent on the fundamental frequency predetermined by the drive motor. In other words, a clearly audible, narrowest possible frequency band is generated, the reference frequency of which corresponds to the speed of the drive shaft and, with changing speed, likewise changes or correspondingly shifts. As a result, the acoustic perception of the current speed is particularly clear.

In an embodiment, in steady-state operation of the work apparatus a single frequency band of the supplementary sound includes an integral multiple of half the fundamental frequency. Depending on the width of the frequency band, it may be sufficient if the integral multiple lies somewhere in this frequency band. Preferably, however, the reference frequency of the frequency band is an integral multiple of half the fundamental frequency. The reference frequency and the integral multiple are therefore congruent. Consequently, the operating sound within the adaptation frequency range is perceptibly increased, without being changed in its characteristic frequencies. Altogether, a rich, powerful sound is produced, increasing confidence in the apparatus without at the same time having to sacrifice any authenticity.

In an embodiment, the supplementary sound in the adaptation frequency range includes a number of frequency bands with at least such reference frequencies of which the integral multiples of half the fundamental frequency are 1 and 2, preferably 1 to 3 and in particular 1 to 5. This achieves the effect that the sound produced sounds balanced, and without any overemphasis of the lower and/or upper frequencies.

The uncorrected operating sound has a profile of an operating sound pressure level that is distributed over the adaptation frequency range. Advantageously, the supplementary sound is adapted to the profile of the operating sound pressure level in such a way that, at the reference frequency of the at least one frequency band, a corresponding overall sound pressure level is at least 3 dB higher than the corresponding operating sound pressure level. As a result, the “peak” in the frequency response of the uncorrected operating sound that is generated on the drive side and acoustically perceived as significant is sufficiently amplified, and is consequently emphasized in its perception as desired.

The uncorrected operating sound has a frequency-dependent profile of the operating sound pressure level with a maximum value. The supplementary sound is expediently adapted to the profile of the operating sound pressure level in such a way that, at the reference frequency of the at least one frequency band, a corresponding overall sound pressure level is not more than 20 dB higher than the maximum value of the operating sound pressure level. This ensures that the acoustic correction is not overemphasized, and that the overall volume does not rise excessively.

In practical operation, a steady state is only rarely achievable. Rather, work activities are generally very dynamic, with varying motor speeds. For better perception of these dynamics, in an embodiment it is provided that, in accelerating or decelerating operation of the work apparatus, the frequency band is shifted in the direction of higher or lower frequencies in comparison with steady-state operation.

Various devices come into consideration for generating the supplementary sound, such as piezo sound generators or the correspondingly activated windings of the electric drive motor. Preferably, the sound generator includes a speaker which is attached to the work apparatus and makes the supplementary sound perceptible to the user. Such a speaker equipped with a coil and a diaphragm can provide a supplementary sound with sufficient variety, that is, with varying frequencies and with the desired spectral distribution of the required quality, with little power consumption within the adaptation frequency range.

Various options come into consideration for the positioning and alignment of the speaker. Preferably, in the customary working position of the work apparatus, the speaker is directed at the head of the user and expediently arranged on the upper side of the work apparatus, whereby the generated supplementary sound is audible clearly and without major damping effects for the user. It may be accommodated as a separate component in a separate housing, but is advantageously integrated in a component of the work apparatus and in particular in a hand protection of the work apparatus. Consequently, the speaker is well protected against external influences without impairment of its effect, without disadvantagously increasing the overall volume of the work apparatus.

Virtually any desired electric work apparatuses can be modified according to the disclosure. The work apparatus taken as a basis is preferably a chain saw or a hedge trimmer. It has been found that here the lack of acoustic feedback without correction and the improvement potential as a result of the sound adaptation according to the disclosure are particularly pronounced.

The embodiments of disclosure are also suitable for retrofitting existing work apparatuses. Provided for this purpose is an assembly for sound adaptation of a handheld work apparatus driven by an electric drive motor which includes a hand protection for the work apparatus and a sound generator with a speaker. The sound generator can preferably be configured to perform the method according to the disclosure summarized above and described in more detail below. In a simple and cost-saving way, an old hand protection can be removed and replaced with an assembly according to the disclosure. As a result, the advantages according to the disclosure described above can be made obtainable in an easy way also in the case of an already existing work apparatus.

In an embodiment, the speaker is integrated in the hand protection. As a result, the speaker and the hand protection form an easily exchangeable structural unit. The sound generator has a generator and amplifier unit for activating the speaker, with which firstly the frequency response of the supplementary sound is generated and then it is output as an amplified output signal to the speaker. This generator and amplifier unit, as part of the assembly according to the disclosure for sound adaptation, can be installed or retrofitted as a separate unit independently of the hand protection in a suitable region of the work apparatus. Preferably, however, also the generator and amplifier unit is integrated in the hand protection. The effort involved in conversion is thereby restricted to a minimum. After the hand protection has been changed, all that is necessary is for a signal connection for the speed of the drive shaft or the drive motor and possibly also a power supply to be provided.

In a further aspect of the disclosure, the sound generator is not necessarily, but only optionally configured for performing an above method according to the disclosure. It is therefore also possible to dispense with the described sound adaptation. In any case, a possibility according to the disclosure is also to output other sounds with or without sound adaptation. Thus, for example, a radio receiver, a music player (MP3 player) or the like may be integrated, the assembly according to the disclosure then being used, for example, to play a radio program or a music file, for example, during breaks in work.

### BRIEF DESCRIPTION OF THE DRAWINGS

The invention will now be described with reference to the drawings wherein:

FIG. 1 shows in a perspective view an electric work apparatus configured according to the disclosure in the example of a chain saw with a speaker integrated in the hand protection for generating the supplementary sound according to the disclosure; and,

FIG. 2 shows in a diagrammatic representation the frequency spectra of the uncorrected operating sound, the supplementary sound and the overall sound thereby achieved.

### DESCRIPTION OF THE PREFERRED EMBODIMENTS

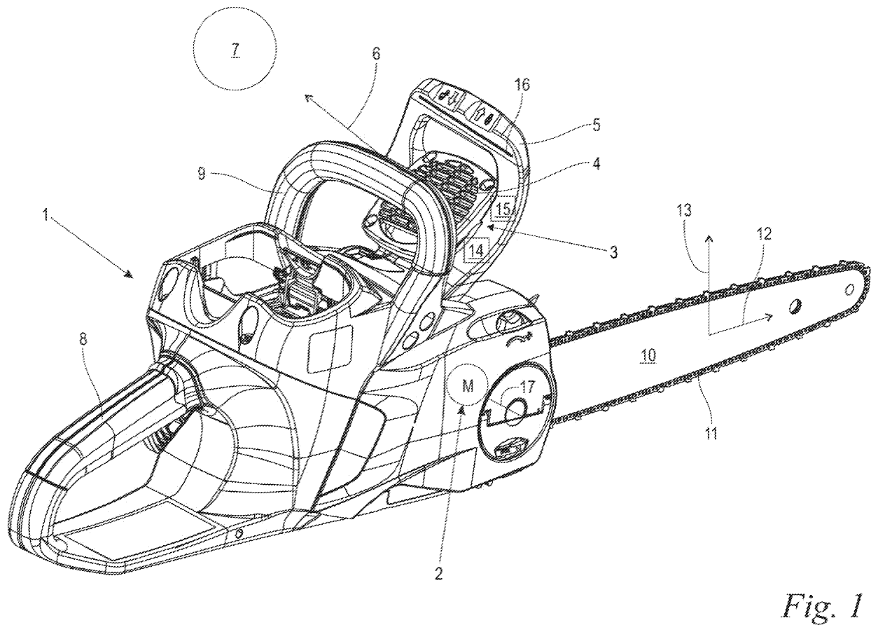

FIG. 1 shows in a perspective view a handheld work apparatus modified according to the disclosure with an only schematically indicated electric drive motor 2. Chosen here as an example of such a work apparatus is a chain saw 1 with a guide bar 10 and with a saw chain 11 running around the guide bar 10 and driven by the drive motor 2. However, an electric hedge trimmer or the like may also be provided, for which then the following description applies in an analogous way.

The drive motor 2 has a schematically indicated drive shaft 17, via which it drives the saw chain 11 by way of a sprocket that is not shown. In the present case this is a direct drive, in which the drive shaft 17 is at the same time also the motor shaft of the drive motor 2. In may however also be expedient to make the drive shaft 17 separate from the motor shaft and, for example in connection with a high-speed drive motor 2, to set it in rotation with reduced speed and increased torque by way of an interposed step-down gear mechanism.

The guide bar 10 extends along a longitudinal axis, which predetermines a longitudinal direction 12 of the chain saw 1. The vertical direction 13 lies in the plane of the guide bar 10 and approximately perpendicular to the longitudinal direction 12. The chain saw 1 is shown here in a customary working position, in which the longitudinal direction 12 is aligned approximately horizontally and the vertical direction 13 is aligned approximately vertically with respect to the direction of gravity. In this customary working position, the chain saw 1 is gripped from above by the user and held with one hand on a rear handle 8 and one hand on a front bale handle 9. As a result, in the customary working position, the only schematically indicated head 7 of the user is above the rear region of the chain saw 1.

The front hand on the bale handle 9 is protected by a hand protection 5 from the saw chain 11 driven by the electric drive motor 2 and running around the guide bar 10. In the event of kickback or other unforeseen movements of the chain saw 1 in an upward/rearward pivoting motion, the hand protection 5 is pressed against the user's front hand. As a result of this and or as a result of the mass inertia of the hand protection, it pivots forwards in relation to the chain saw and immediately releases a chain brake that is not shown.

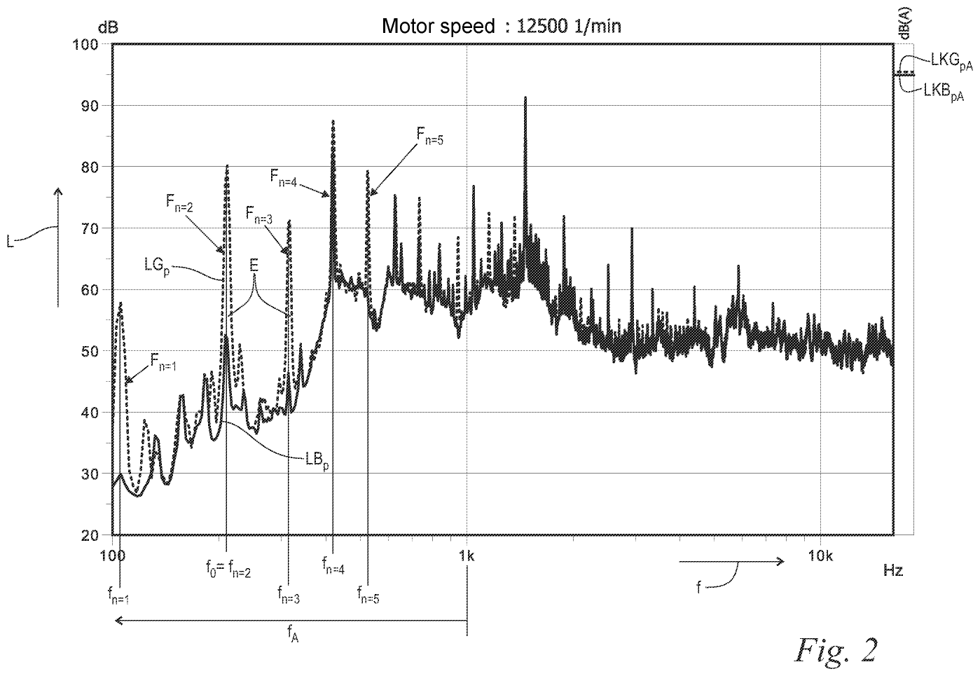

Via the electric drive motor 2 and the saw chain 11 driven by it, during operation the chain saw 1 generates a sound, which is subjected to a sound adaptation in the way described in more detail below. Without this sound adaptation, the sound is referred to hereinafter in connection with FIG. 2 as uncorrected operating sound. For the sound adaptation and/or other purposes described further below, the chain saw 1 has a sound generator 3.

Part of the sound generator 3 is a speaker 4 and also a generator and amplifier unit 14, which is only schematically indicated as a block. The generator and amplifier unit 14 generates the frequency response of a sound and amplifies it to a suitable output level as an output signal in such a way that the speaker 4 outputs the output signal as sound of the desired volume or with the desired sound pressure level L_{P} (FIG. 2).

In an aspect of the disclosure, a supplementary sound described below in connection with FIG. 2 is generated by the sound generator 3 and made perceptible to the user of the chain saw 1. Alternatively or additionally, the sound generator 3 may be connected to a radio receiver 15, schematically indicated as a block, or to some other unit for playing music, such as for example an MP3 player. In this case, the sound generator 3 may output a radio program, music and/or the like and be used for example for entertainment during breaks in work.

The speaker 4 may for example be integrated in hearing protection, which is worn on the user's ears. For good perceptibility of the sound generated, in particular the supplementary sound (FIG. 2) even without such adapted hearing protection, the speaker 4 in the embodiment shown is arranged on the upper side of the chain saw 1. It is also integrated in a component of the chain saw 1, for which a housing part or the like may be expedient. In the embodiment shown, the speaker 4 is integrated in the hand protection 5. This means that part of the hand protection 5, here an injection-moulded part, receives the speaker 4 and thereby serves as a housing for it. The corresponding portion of the hand protection 5 is for this purpose configured as a protective mesh, which is transmissive to sound but otherwise protects the speaker 4 from external influences.

It may be expedient to position the generator and amplifier unit 14 and/or the radio receiver 15 in the housing of the work apparatus or at some other suitable location. In the embodiment shown, in addition to the speaker 4, the generator and amplifier unit 14 and the radio receiver 15 are also integrated in the hand protection 5. For supplying the radio receiver 15 with a received signal, also integrated in the hand protection 5 is a schematically indicated antenna 16. This forms an independent functional unit, which as an exchangeable unit can be exchanged for a conventional hand protection 5, and whereby a conventional work apparatus can be retrofitted with the sound function described here. Depending on the configuration, it is therefore an assembly for playing a radio or music program and/or, in a way corresponding to the embodiment shown here, an assembly for sound adaptation of the work apparatus in the way described in more detail further below.

The speaker 4 may have various suitable structural forms and is constructed here in the usual way with a diaphragm, a permanent magnet and an electrical coil. The speaker has a central transmission direction 6, which in the present case points in the direction normal to the plane of the diaphragm. The speaker 4 is fastened to the chain saw 1 in such a way that, in the customary working position shown, it is directed with its transmission direction 6 towards the head 7 of the user. For this purpose, the transmission direction 6 is directed at least upwards in the vertical direction 13, here also additionally rearwards in the longitudinal direction 12. There is no lateral inclination, or at least it is less pronounced than the rearward inclination, and so the transmission direction 6 lies at least principally in the plane defined by the longitudinal direction 12 and the vertical direction 13.

FIG. 2 shows in a diagrammatic representation the spectral distributions, that is, the frequency responses of the sounds generated during operation by the chain saw 1 as shown in FIG. 1. In this case, the frequency f of the sounds in Hz is plotted on the horizontal abscissa and the sound pressure level L_{P} of the respective sounds in dB is plotted on the vertical ordinate. This is a sound pressure level L_{P} determined in accordance with ISO 22868, measured with a measuring microphone at a simulated location of the user's ear, to be specific in the vertical direction 13 approximately 700 mm above the bale handle 9 and in the longitudinal direction 12 approximately in the middle of the apparatus body, which is behind the guide bar 10 to the rear. Without already going into detail now, it can be seen at first glance that the spectral distribution of the sound pressure level L_{P} of the electrically driven work apparatus taken as a basis here can be divided into two regions. Above a frequency f of approximately 1 kHz, the level profile does have various peaks and ripples, but apart from that is on average within a comparatively narrow band of level values. Below this frequency f of approximately 1 kHz, however, the sound pressure level L_{P} has a tendency to fall significantly to lower frequencies, that is apart from a few peaks.

Firstly, the spectral distribution, that is, the frequency response of the uncorrected operating sound, will be discussed. This is the operating sound generated by the work apparatus, without the sound generator 3 (FIG. 1) being active. The profile of the operating sound pressure level LB_{P} of the operating sound is shown by a solid line. For the example of a measurement taken here as a basis, the electric drive motor 2 or the drive shaft 17 operates at a speed of 12 500 rpm or 12 500 1/min, which corresponds to a fundamental frequency f₀ of 208 Hz. At the fundamental frequency f₀, the frequency spectrum of the operating sound, that is, the profile of the operating sound level LB_{P}, naturally has a peak over the frequency f. Further peaks are found at integral multiples n of half the fundamental frequency f₀, that is, at fₙ₌₁, fₙ₌₂, fₙ₌₃ and so on, which is generated by corresponding harmonics of the drive motor 2 and the tool, that is, in this instance the saw chain 11. These are regarded in the context of the disclosure as characteristic of the acoustic feedback of the chain saw 1 to the user.

The chain saw 1 and its sound generator 3 are configured for performing the method according to the disclosure, whereby in addition to the uncorrected operating sound a supplementary sound is generated via the sound generator 3 and is made perceptible for the user by way of the speaker 4. The supplementary sound adds to the uncorrected operating sound to form an overall sound with an overall sound pressure level LG_{P}, the frequency response of which, that is, level profile over the frequency f, is shown in FIG. 2 by a dashed line.

Firstly, it is evident in FIG. 2 that the main component of the supplementary sound lies in an adaptation frequency range f_{A} below 1 kHz. The supplementary sound has sound energy E distributed over its frequency range, which can be understood here as the area between the solid line of the operating sound pressure level LB_{P} of the operating sound and the dashed line of the overall sound pressure level LG_{P} of the overall sound pressure level. It is noticeable that, above the adaptation frequency range f_{A}, that is, above approximately 1 kHz, the supplementary sound does not play a role, or plays only a minor role. This specifically means that at least 70%, preferably at least 80% and in the embodiment shown at least 90% of the sound energy E of the supplementary sound is generated in the adaptation frequency range f_{A}. The falling region of the uncorrected operating sound already mentioned above is therefore as it were at least partially filled acoustically, while the higher frequency range above 1 kHz remains substantially unchanged.

Since the sound correction according to the disclosure takes place primarily in the adaptation frequency range f_{A}, that is, below 1 kHz, this has a first important consequence: since at these low frequencies the uncorrected operating sound pressure level LB_{P} is comparatively low, the perceived overall volume is scarcely increased at all by playing the supplementary sound. In the example specifically shown, the uncorrected operating sound has an A-weighted cumulative operating sound pressure level LkB_{pA}, determined over the audible frequency range, of 94.9 dB(A), while a corresponding A-weighted cumulative overall sound pressure level LkG_{pA} of the overall sound resulting from the uncorrected operating sound and the supplementary sound E is scarcely any more, to be specific only 95.4 dB(A). Altogether, the supplementary sound is set to such a level that the A-weighted cumulative overall sound pressure level LkG_{pA} is not more than 1.0 dB(A) and in the present case not more than 0.5 dB(A) greater than the A-weighted cumulative operating sound pressure level LkB_{pA}.

The region of the uncorrected operating sound B of a level falling to lower frequencies is not simply just uniformly “filled” within the adaptation frequency range f_{A}. Rather, the speed of the drive shaft 17 for the tool, that is, here for the saw chain 11, is used as a fundamental frequency f₀ for establishing the supplementary sound E, while the supplementary sound E is then set as dependent on the fundamental frequency f₀ as follows:

The supplementary sound is generated in such a way that it includes in the adaptation frequency range f_{A} at least one single frequency band Fₙ, such a frequency band Fₙ in each case having a reference frequency fₙ. The term reference frequency fₙ is used here to mean the frequency f at which the sound pressure level is a maximum within this frequency band Fₙ. According to the representation as shown in FIG. 2, the supplementary sound within the adaptation frequency range f_{A} has a number of such frequency bands Fₙ₌₁, Fₙ₌₂, Fₙ₌₃, Fₙ₌₄, Fₙ₌₅ with associated reference frequencies fₙ₌₁, fₙ₌₂, fₙ₌₃, fₙ₌₄, fₙ₌₅, which are evident as peaks with limited bandwidth. Instead of a configuration with a specific bandwidth, frequency bands Fₙ in the form of approximated spikes without a relevant bandwidth may also be expedient. In any case, the reference frequencies fₙ are set as dependent on the fundamental frequency f₀ predetermined by the drive motor 2 or by the speed of the drive shaft 17. This means firstly that, with a changing speed or fundamental frequency f₀, the reference frequencies fₙ are also shifted correspondingly. A higher speed or fundamental frequency f₀ leads to higher reference frequencies fₙ and a lower speed or fundamental frequency f₀ leads to correspondingly lower reference frequencies fₙ.

For the steady-state case of a constant speed or fundamental frequency f₀ shown in FIG. 2, it is provided in the embodiment shown that at least one of the frequency bands Fₙ of the supplementary sound includes an integral multiple n of half the fundamental frequency f₀. In the present case, this applies to a number of frequency bands Fₙ of the supplementary sound, and in particular to the first five frequency bands Fₙ₌₁, Fₙ₌₂, Fₙ₌₃, Fₙ₌₄, Fₙ₌₅, in the case of which therefore the integral multiples n of half the fundamental frequency f₀ are in the present case 1 to 5. Of course, still further frequency bands with additional integral multiples n may also be provided. Similarly, it may be expedient in the context of the disclosure to omit individual frequency bands. In any case, such frequency bands of the supplementary sound with integral multiples of n equals 1 and 2 and in particular of n equals 1 to 3 should preferably be present.

The associated reference frequencies fₙ, here fₙ₌₁, fₙ₌₂, fₙ₌₃, fₙ₌₄, fₙ₌₅ do not have to coincide exactly with the integral multiples n of half the fundamental frequency f₀, though the integral multiples n of half the fundamental frequency f₀ in the steady state should lie at least within the frequency bands Fₙ, here Fₙ₌₁, Fₙ₌₂, Fₙ₌₃, Fₙ₌₄, Fₙ₌₅. In the present case, however, the mentioned coincidence applies, and accordingly the reference frequencies fₙ₌₁, fₙ₌₂, fₙ₌₃, fₙ₌₄, fₙ₌₅ of the frequency bands Fₙ₌₁, Fₙ₌₂, Fₙ₌₃, Fₙ₌₄, Fₙ₌₅ are set to the assigned integral multiples n of half the fundamental frequency f₀. In any case it is achieved that the peaks at the integral multiples n of half the fundamental frequency f₀, that is, at fₙ₌₁, fₙ₌₂, fₙ₌₃ and so on, which are perceived to be characteristic of the operating state and are important for acoustic feedback, are amplified in the profile of the operating sound level L_{B} and are made better perceptible in the form of the overall sound G with a corresponding profile of the overall sound level L_{G}.

Furthermore, it is also evident that certain lower and upper limits for the intensity of the supplementary sound are maintained. On the one hand, the supplementary sound is adapted to the profile of the operating sound pressure level LBₚ in such a way that, at the selected reference frequencies fₙ of the frequency band Fₙ, the corresponding overall sound pressure level LGₚ produced is at least 3 dB higher than the corresponding operating sound pressure level LBₚ. By way of example, reference may be made here to the reference frequency f₀=fₙ₌₂, where the overall sound pressure level LGₚ is approximately 80 dB, and consequently 28 dB, that is, at least 3 dB, higher than the corresponding operating sound pressure level LBₚ at a level of 52 dB. On the other hand, a certain upper limit is also not exceeded: at the selected reference frequencies fₙ of the frequency bands Fₙ, the corresponding overall sound pressure level LGₚ produced is not more than 40 dB and in particular not more than 30 dB higher than the corresponding operating sound pressure level LBₚ. Once again, reference may be made here by way of example to the reference frequency f₀=fₙ₌₂, where the overall sound pressure level LGₚ is approximately 80 dB and consequently 28 dB, that is, not more than 30 dB, higher than the corresponding operating sound pressure level LBₚ at a level of 52 dB.

The state described above can also be maintained in non-steady-state operation, when accelerating and/or decelerating. Preferably, however, here the frequency band Fₙ or the frequency bands Fₙ₌₁, Fₙ₌₂, Fₙ₌₃, Fₙ₌₄, Fₙ₌₅ are shifted in the direction of higher or lower frequencies in comparison with steady-state operation. As a result, the dynamics of working operation are acoustically emphasised more significantly.

It is understood that the foregoing description is that of the preferred embodiments of the invention and that various changes and modifications may be made thereto without departing from the spirit and scope of the invention as defined in the appended claims.

What is claimed is:

1. A method for sound adaptation of a handheld work apparatus via a sound generator, wherein the handheld work apparatus includes an electric motor configured to drive the work apparatus, wherein the work apparatus generates during operation an uncorrected operating sound with an operating sound pressure level, the method comprising:
generating a supplementary sound via the sound generator in addition to the uncorrected operating sound during operation; and,
overlaying the supplementary sound on the uncorrected operating sound to form an overall sound with an overall sound pressure level, wherein a main component of the supplementary sound lies in an adaptation frequency range below 1 kHz.

2. The method of claim 1, wherein the uncorrected operating sound has an A-weighted cumulative operating sound pressure level; an overall sound resulting from the uncorrected operating sound and the supplementary sound has a further A-weighted cumulative overall sound pressure level; and, the supplementary sound is set at such a level that the further A-weighted cumulative overall sound pressure level is not more than 1.0 dB greater than the A-weighted cumulative operating sound pressure level.

3. The method of claim 1, wherein the supplementary sound has sound energy distributed over a frequency range, at least 70% of the sound energy of the supplementary sound being generated in the adaptation frequency range.

4. The method of claim 1, wherein a speed of a drive shaft is used as a fundamental frequency for establishing the supplementary sound; and, the supplementary sound is set in dependence upon the fundamental frequency.

5. The method of claim 4, wherein the supplementary sound includes in the adaptation frequency range at least one single frequency band; the frequency band includes a reference frequency with a maximum sound pressure level; and, the reference frequency is set in dependence upon the fundamental frequency predetermined by the electric drive motor.

6. The method of claim 5, wherein, in steady-state operation of the work apparatus, the single frequency band of the supplementary sound includes an integral multiple of half the fundamental frequency; and, the reference frequency of the frequency band is an integral multiple of half the fundamental frequency.

7. The method of claim 6, wherein the supplementary sound in the adaptation frequency range includes a plurality of frequency bands including reference frequencies of which the integral multiples (n) are 1 and 2.

8. The method of claim 5, wherein the uncorrected operating sound has a profile of an operating sound pressure level that is distributed over the adaptation frequency range; and, the supplementary sound is adapted to the profile of the operating sound pressure level such that, at the reference frequency of the at least one frequency band, a corresponding overall sound pressure level produced is at least 3 dB higher than the corresponding operating sound pressure level.

9. The method of claim 5, wherein the uncorrected operating sound has a profile of an operating sound pressure level that is distributed over the adaptation frequency range; and, the supplementary sound is adapted to the profile of the operating sound pressure level such that, at the reference frequency of the at least one frequency band, a corresponding overall sound pressure level produced is not more than 40 dB higher than the corresponding operating sound pressure level.

10. The method of claim 5, wherein, in accelerating or decelerating operation of the work apparatus, the frequency band is shifted in a direction of higher or lower frequencies in comparison with steady-state operation.

11. A handheld work apparatus comprising:
an electric drive motor;
a sound generator;
wherein the work apparatus generates, during operation, an uncorrected operating sound with an operating sound pressure level;
said sound generator being configured to
generate a supplementary sound via said sound generator in addition to the uncorrected operating sound during operation; and,
overlay the supplementary sound on the uncorrected operating sound to form an overall sound pressure level, wherein a main component of the supplementary sound lies in an adaptation frequency range below 1 kHz.

12. The handheld work apparatus of claim 11, wherein said sound generator includes a speaker attached to the work apparatus and is configured to makes the supplementary sound perceptible to a user.

13. The handheld work apparatus of claim 12, wherein, in a customary working position of the work apparatus, said speaker is directed at a head of the user.

14. The handheld work apparatus of claim 12, wherein the work apparatus defines an upper side; and, said speaker is arranged on said upper side of the work apparatus.

15. The handheld work apparatus of claim 12, wherein said speaker is integrated in a component of the work apparatus.

16. The handheld work apparatus of claim 11, wherein the work apparatus is a chain saw or a hedge trimmer.

17. An assembly for sound adaptation of a handheld work apparatus driven by an electric drive motor, the assembly comprising:
a hand protection of the work apparatus;
a sound generator having a speaker;
wherein the work apparatus generates, during operation, an uncorrected operating sound with an operating sound pressure level;
said sound generator being configured to
generate a supplementary sound via said sound generator in addition to the uncorrected operating sound during operation; and,
overlay the supplementary sound on the uncorrected operating sound to form an overall sound pressure level, wherein a main component of the supplementary sound lies in an adaptation frequency range below 1 kHz.

18. The assembly of claim 17, wherein said speaker is integrated in said hand protection.

19. The assembly of claim 17, wherein said sound generator has a generator and amplifier unit for activating said speaker; and, said generator and amplifier unit is integrated in said hand protection.
